(19) United States
(12) Patent Application Publication
(10) Pub. No.: US 2007/0015373 A1
(43) Pub. Date: Jan. 18, 2007

(54) Semiconductor device and method of processing a semiconductor substrate

(75) Inventors: Christopher Steven Cowen, (US); Larry Burton Rowland, Scotia, NY (US); Jesse Berkley Tucker, Niskayuna, NY (US); Jeffrey Bernard Fedison, Niskayuna, NY (US); Richard Joseph Saia, Schenectady, NY (US); Kevin Matthew Durocher, Waterford, NY (US)

Correspondence Address: GENERAL ELECTRIC COMPANY;GLOBAL RESEARCH, PATENT DOCKET RM. BLDG. K1-4A59, NISKAYUNA, NY, 12309, US

(73) Assignee: General Electric Company

(21) Appl. No.: 11/181,427

(22) Filed: Jul. 13, 2005

(51) Int. Cl. H01L 21/31; H01L 21/469

(52) U.S. Cl. 438/758

(57) ABSTRACT

A method of processing a semiconductor substrate is provided. The method includes depositing an amorphous hydrogenated carbon film on a semiconductor substrate using a low temperature plasma deposition process and performing at least one high temperature processing step on the semiconductor substrate. The SiC substrate is processed by ion implanting at least one dopant species into at least one selected region of the SiC substrate, depositing a amorphous hydrogenated carbon film on the SiC substrate using a plasma enhanced chemical vapor deposition (PECVD) process, performing at least one high temperature processing step on the SiC substrate and removing the amorphous hydrogenated carbon film after performing the high temperature processing step.

### BACKGROUND

The invention relates generally to a method of processing a semiconductor substrate. More particularly, the invention relates to a method of processing a semiconductor substrate to reduce or prevent step bunching that occurs during high temperature processes so as to produce a smoother surface.

Modern semiconductor devices, including nano-scale devices, require control of surface and interface structures at the atomic level. Morphological defects, such as step-bunching, that occur during high temperature processing of semiconductors, are a major concern for device fabrication. Compound semiconductors, such as silicon carbide (SiC), have wide band gaps, large electrical break down fields, high thermal conductivity and outstanding chemical inertness making them attractive for high power and/or high frequency devices, as well as for devices operating at high temperature and/or under harsh environments. However, doping in these materials is not simple. Doping requires ion implantation and post annealing to repair the lattice damage caused during ion implantation and/or to activate the dopants. Post anneals typically lead to undesirable surface roughening and out-diffusion of some implanted ions. The surface roughning is generally smoothed by chemical/mechanical polishing or dry etching, which are labor-intensive and time consuming processes. Therefore, there is a need for the development of a semiconducting processing technique to suppress surface roughening and dopant out-diffusion during semiconductor high temperature processing.

### BRIEF DESCRIPTION OF THE INVENTION

Briefly, in accordance with one embodiment of the present invention, a method of processing a semiconductor substrate is provided. The method includes depositing an amorphous hydrogenated carbon film on a semiconductor substrate using a low temperature plasma deposition process and performing at least one high temperature processing step on the semiconductor substrate.

In accordance with another embodiment, a method of processing a substrate including SiC is provided. The method includes depositing an amorphous hydrogenated carbon film on SiC using a plasma enhanced chemical vapor deposition (PECVD) process and performing an annealing step on the substrate.

In another embodiment, a method of processing a substrate including SiC is provided. The method includes depositing an amorphous hydrogenated carbon film on the substrate using a PECVD process, performing an annealing step on the substrate, ion implanting at least a p-type dopant species into selected regions of SiC, and removing the amorphous hydrogenated carbon film after performing the annealing step. The ion implanting is performed prior to the deposition of the amorphous hydrogenated carbon film.

In yet another embodiment, a semiconductor device including a SiC substrate is provided. The SiC substrate is processed by ion implanting at least one dopant species into at least one selected region of the SiC substrate, depositing an amorphous hydrogenated carbon film on the SiC substrate using a PECVD process, performing at least one high temperature processing step on the SiC substrate and removing the amorphous hydrogenated carbon film after performing the high temperature processing step(s).

### BRIEF DESCRIPTION OF DRAWINGS

These and other features, aspects, and advantages of the present invention will become better understood when the following detailed description is read with reference to the accompanying drawings in which like characters represent like parts throughout the drawings, wherein:

FIG. 1 is a flow chart illustrating a method of processing a semiconductor substrate, according to one embodiment of the present invention;

FIG. 2 is a flow chart illustrating a method of processing a semiconductor substrate, according to an exemplary embodiment of the present invention;

FIG. 3 schematically depicts a semiconductor substrate coated with an amorphous hydrogenated carbon film;

FIG. 4 schematically depicts a semiconductor thin film coated with an amorphous hydrogenated carbon film; and

FIG. 5 depicts optical dark field images of SIC substrates processed by a conventional method and processed using the present method, respectively.

### DETAILED DESCRIPTION

As used herein, “amorphous hydrogenated carbon films” refers to substantially or completely amorphous films including carbon, which are often termed diamond-like carbon (DLC) films in the art. The amorphous hydrogenated carbon films may be covalently bonded in a random system or in an interpenetrating system. The amorphous hydrogenated carbon films of this invention may contain clustering of atoms that give them a short-range order but are essentially void of medium and long range ordering that lead to micro or macro crystallinity. The term “amorphous” means a substantially randomly-ordered non-crystalline material having no x-ray diffraction peaks or modest x-ray diffraction peaks. When atomic clustering is present, it typically occurs over dimensions that are small compared to the wavelength of radiation. “Depositing a film” as used herein, implies that the film is directly in contact with the substrate, bound or otherwise, or the film is in contact with intervening layers, bound or otherwise.

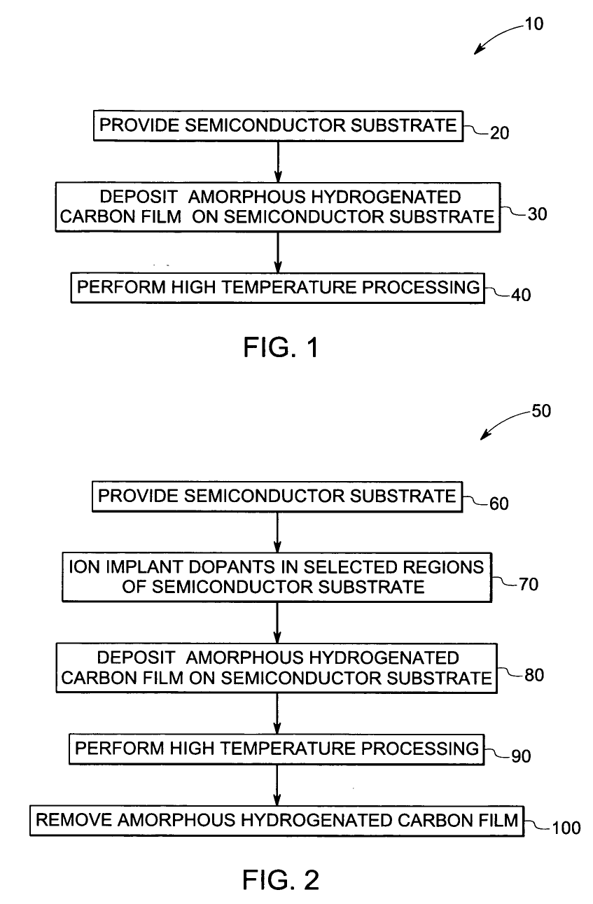

FIG. 1 is a flow chart of a method 10 of processing a substrate, according to one embodiment of the present invention. The method includes providing a semiconductor substrate in step 20, depositing an amorphous hydrogenated carbon film on a semiconductor substrate using a low temperature plasma deposition process in step 30 and performing at least one high temperature processing step on the semiconductor substrate in step 40. The method of processing a semiconductor substrate of the present invention may be applied to any semiconductor substrate. Compound semiconductors that are prone to lattice damages while processing at high temperatures benefit from this method. Accordingly, in particular embodiments, the semiconductor substrate is a compound semiconductor. Non-limiting examples of compound semiconductors include SiC, SiGe, GaAs, GaN, GaP. In one exemplary embodiment, the semiconductor substrate is SiC. As used here, the term “substrate” may include one or more layers. For example, the substrate may include a semiconducting thin film grown on a base substrate, for example, a SiC thin film epitaxially grown on a SiC substrate.

Films suitable for these applications include a carbon network chemically stabilized by hydrogen atoms resulting in an amorphous network termed diamond-like carbon film or amorphous hydrogenated carbon film.

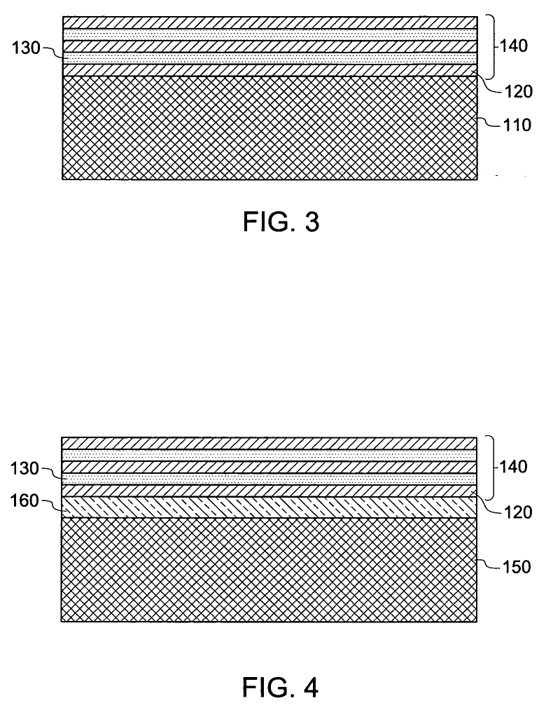

In some embodiments, the film includes alternate hard and soft layers. FIG. 3 illustrates a film 140 comprising hard layers 120 and soft layers 130 deposited alternately on a substrate 110. Hard layers of the amorphous hydrogenated carbon film have better hermetic properties than the soft layers of the film. Hard layers, however, are deposited under high stresses, and generally can not be deposited at a thickness above about 1000 Angstoms without cracking. Beneficially, by alternating the hard film layers with lower stress, softer film layers, a conformal composite, pin-hole free film can be deposited to a thickness of several microns. According to a particular embodiment, a first layer 120 of the composite film comprises a hard layer. This is beneficial because hard layers have better adhesion properties than soft layers. The soft layer, deposited at high pressure, has good adhesion to the hard layer which is depoited at low pressure. Further, the soft layer has very good dielectric properties and lower electrical leakage as compared to the hard layer. According to a particular embodiment, a cap (outer) layer 120 of the composite film comprises a hard layer. This is beneficial because hard layers offer more scratch protection than the soft layers. According to a particular embodiment, a number of layers of hard film are alternately applied with a number of layers of soft film until a desired thickness is achieved. In some embodiments, the hard layer has a thickness in a range from about 100 Angtroms to about 500 Angstroms, and the soft layer has a thickness in a range of about 300 Angstroms to about 1000 Angstroms. An exemplary thickness range of the composite film is from about 0.1 micrometers to about 2 micrometers. In one embodiment, this thickness range is achieved with at least five layers of hard film and at least 4 layers of soft film. The film may be a blanket film or patterned using a stencil mask or other method after deposition.

FIG. 4 illustrates a film 140 comprising hard layers 120 and soft layers 130 deposited alternately on a semiconductor thin film 160 grown epitaxially on a substrate 150. The film and the layers have the same composition and thickness characteristics as described above for the previous embodiment.

The amorphous hydrogenated carbon film may be deposited by any low temperature plasma deposition technique. In an exemplary embodiment, the amorphous hydrogenated carbon film is deposited by a plasma enhanced chemical vapor deposition (PECVD) process. PECVD may be advantageous as it is a low temperature process, and it facilitates the growth of homogeneous films, which can be deposited in a large area on any kind of substrate at a high deposition rate. “Low temperature” as used herein implies temperature less than about 150° C. For PECVD of amorphous hydrogenated carbon, any saturated or unsaturated hydrocarbon precursor with sufficient vapor pressure may be used as a source material. Non-limiting examples of suitable source materials include acetylene, benzene, butane, cyclohexane, ethane, ethylene, hexane, isopropane, methane, pentene, propane, methylethylketone, and propylene. In one exemplary embodiment, the film is deposited using an organic precursor which includes oxygen such as a methylethylketone (MEK) organic precursor. The precursor gas substantially influences the film properties such as density, hydrogen content, refractive index etc and hence a particular precursor is chosen depending on the nature of the film desired. The nature of the film also depends on the substrate material, and the energy of carbon ions during deposition, which may be controlled by the deposition power and the pressure within the chamber.

The amorphous hydrogenated carbon film, in one embodyment, is deposited in multiple hard and soft layers by cycling the process pressure during deposition. Chemical vapor deposition may be performed in a standard parallel plate plasma reactor at temperatures below 150° C. The hard or soft property of the film can be obtained by controlling the DC bias voltage during film deposition. A soft layer can be deposited in a range of about −100 volts to about −300 volts. At increasing magnitudes of the bias voltage, the film becomes harder and more scratch resistant. In one embodiment, the magnitude of the bias voltage for hard layer deposition is greater than about −300 volts, and more particularly the bias voltage magnitude is in a range of about −450 volts to about −470 volts. In the industry, the words “greater than” with respect to “bias voltage” are used to mean that the bias voltage has a greater magnitude (even though, because negative numbers are involved, a greater magnitude technically results in a lower bias voltage). The phrase “bias voltage magnitude is greater than” in the present invention description means that the bias voltage has a greater magnitude and a corresponding more negative value.

The DC self bias voltage generated at the surface of the RF powered electrode in a plasma chemical vapor deposition (CVD) reactor is a measure of the amount of ion bombardment present. The bias voltage and the amount of ion bombardment in a plasma discharge decreases as the chamber pressure is increased. As a result, a film deposited at low pressure is hard, and a film deposited at high pressure is soft. The change in bias voltage can also be accomplished by changing the RF power level, but lowering the bias voltage by lowering the power results in low deposition rates.

Fabrication of semiconductor pn junctions, Schottky diodes or other types of transistors require ion implantation of dopants in selected regions of the substrate. For example, a relatively low dose boron implantation of about 10¹⁴ cm⁻² is used for device periphery protection with guard ring, or junction termination extension, as well as as buried p-doped regions in p-i-n diodes. P-doped regions in merged p-i-n Schottky rectifiers and p-i-n diodes are typically formed by aluminium implantation with a dose of about 10¹⁵ cm⁻². When a semiconductor crystal undergoes ion implantation, it may suffer implantation damage, so that high temperature treatment such as annealing must be performed to restore the damaged crystallinity and to sufficiently raise the electrical activation of the ion-implanted dopants. “High temperature” as used herein implies temperatures higher than about 800° C. In the case of silicon carbide, the high temperature processing step is performed at a temperature of at least about 1400 degrees C. High temperature annealing in semiconductors leads to surface lattice damage, such as step bunching and formations of microterraces. This surface lattice damage is thought to be caused by the sublimation of surface species such as Si, Si₂C, SiC₂, etc. This surface lattice damage may result in a perturbed device performance or in unpredicable degradation of the devices, especially when there are very fine channels present in the devices. In such devices it is important to achieve roughness of the channel layer less than or equal to about 1 nm. The method of the present invention offers a solution to the above problem by providing means to reduce or prevent lattice damage that occurs in semiconductors during high temperature processing. By depositing an amorphous hydrogenated carbon film on the semiconductor substrate, any dangling bonds are paired with carbon at the high anneal temperatures. The carbon layer prevents sublimation of the substance from the substrate and thus prevents or reduces lattice damage.

In some embodiments, the method includes an optional step of ion implanting at least one dopant species into the semiconductor substrate, and removing the amorphous hydrogenated carbon film after performing the high temperature processing step(s). The ion implanting is performed prior to depositing the amorphous hydrogenated carbon film. This exemplary embodiment is illustrated by the flowchart shown in FIG. 2. The method 50 includes the step of providing a substrate in step 60, ion implanting dopants in selected substrate regions in step 70, depositing a amorphous hydrogenated carbon film in step 80, performing at least one high temperature processing in step 90 and removing the amorphous hydrogenated carbon film in step 100.

The amorphous hydrogenated carbon film may be removed by any process for removing coatings/layers/films. For example, the amorphous hydrogenated carbon film may be removed by wet or dry chemical etching. The amorphous hydrogenated carbon film may be removed using an oxygen plasma mask process, by thermal oxidation, or by argon ion laser ablation. In one exemplary embodiment, the amorphous hydrogenated carbon film is removed using an oxygen plasma.

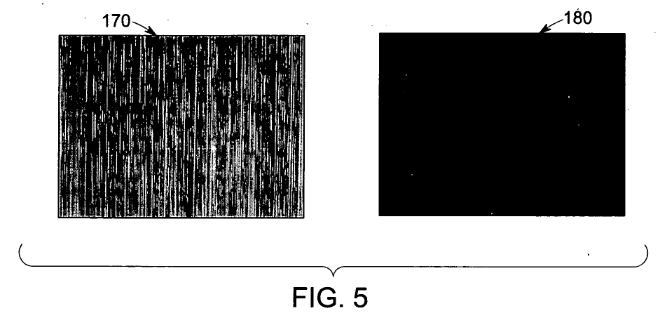

In one exemplary embodiment, a method of processing a substrate comprising SiC is provided. The method includes depositing an amorphous hydrogenated carbon film on the substrate using a PECVD process, performing an annealing step on the substrate, ion implanting at least one p-type dopant species into selected regions of SiC and removing the amorphous hydrogenated carbon film after performing the annealing step. Typically used p-type dopants include, but are not limited to aluminum and boron. Another exemplary p-type dopant is gallium. Typically used n-type dopants include, but are not limited to, nitrogen and phosphorous. The deposition of amorphous hydrogenated carbon prior to high temperature treatment reduces step bunching and hence improves device performance, such as on-resistance and blocking voltage of power devices where high electric field occur at the surface. It may also preserve long term functionality of low-field devices. FIG. 5 shows optical dark field images of two SiC semiconductor substrates subjected to high temperature anneals. The first SiC wafer 170 was subjected to a high temperature anneal without amorphous hydrogenated carbon capping, and the second SiC wafer 180 was subjected to a high temperature anneal with amorphous hydrogenated carbon capping. From the images shown in FIG. 5, it is clear that amorphous hydrogenated carbon capping significantly reduces surface roughening of semiconductor substrates that occur during high temperature processing.

In another aspect, the invention also provides a semiconductor device comprising a SiC substrate. The semiconductor wafer is processed by a method that includes the steps of ion implanting at least one dopant species into selected regions of SiC, depositing an amorphous hydrogenated carbon film on the SiC using a PECVD process, performing a high temperature process step on the SiC substrate and removing the amorphous hydrogenated carbon film after performing the annealing step. The semiconductor device may be any device selected from the group consisting of a p-n diode, a p-i-n diode, schottky diode, a metal oxide field effect transistor, a insulated gate bipolar transistor, thyristor, or gate turn-off thyristors. The improved performance of the electrical properties of the present invention contribute to improved performance of the apparatus involved such as a power converter, an inverter, electronics sensors, detectors, and associated control electronics, or signal conditioning electronics.

The method of the present invention offers distinct advantages over the resist bake method used in the art. PECVD provides a hydrogenated carbon film as compared to baked on resist, which can be subject to impurities and be cross-linked with temperature making it more difficult to remove. Using CVD carbon, instead of baked on resist, reduces the number of steps prior to anneal. With a CVD carbon film, the substrate does not have to be cycled through a bake prior to anneal, and the process is faster and cleaner than the resist bake technique. The CVD process also facilitates depositing patterned films easily. Patterned films may need to be deposited, as many semiconductor devices may have several areas including regions selectively implanted by different dopants and un-implanted regions. Depositing amorphous hydrogenated carbon by PECVD method is also less labor-intensive and is more cost effective as compared to the baked-on resist capping layers used in the art. Moreover, the contamination from the baked-on capping layer may degrade the device performance. In addition, the conformality of the PECVD depostion technique can provide more uniform surface coverage on processed semiconductor substrates with significant topology. Devices with significant topology at this stage of processing includes the UMOSFET, which has a trench that does not get uniformly covered using spin-coating of photoresist. Thus, amorphous hydrogenated carbon film proves to be a good candiate for numerous applications.

The following example serves to illustrate the features and advantages offered by the present invention, and not intended to limit the invention thereto.

Example: Method of processing SiC substrate

The following example describes a preparation method.

In this example, a SiC wafer was cleaned by RCA cleaning method using a mixture of sulphuric acid and hydrogen peroxide. The cleaned SiC substrate was plasma cleaned within the deposition chamber. The native oxide was removed by PECVD argon sputter etch for 1 minute. During the sputter etch, the pressure within the chamber was maintained at 100 millitorr, the argon flow rate was 40 sccm (standard cubic centimeters per minute) and the power was maintained at 70 W. An amorphous hydrogenated carbon film was deposited on this SiC wafer by PECVD using methyl ethyl ketone (MEK) as the precursor. The film was deposited as alternate hard and soft layers. Four hard layers, each having a thickness of 450 Å were alternated with four soft layers, each having a thickness of 3000 Å. A cap layer of hard carbon was deposited to a thickness of 1000 Å. with the total thickness of all the layers being 1.45 microns. During deposition, the pressure was automatically cycled using a microprocessor, and the electrode temperature was maintained at 50 degrees C. to reduce the redeposition of volatile organic species in the plasma. Each of the four layers of hard hydrogenated carbon was deposited at a rate of 200 Å/min with a MEK flow of 40 sccm, a power of 50 Watts (DC bias −470 volts), and a pressure of 30 mtorr. Each of the four layers of soft amorphous hydrogenated carbon was deposited at a rate of 300 Å/min with a MEK flow of 40 sccm, a power of 50 W (DC bias −110 volts), and a pressure of 500 mtorr. The cap layer of hard amorphous hydrogenated carbon was deposited at a rate of 200 Å/min with a MEK flow of 40 sccm, a power of 50 W (DC bias −470 volts), and a pressure of 30 mtorr. The SiC substrate covered with the amorphous hydrogenated carbon was annealed at 1700° C. for 30 minutes. The amorphous hydrogenated carbon cap was removed using an oxygen plasma etch process. Barrell ash was used as the plasma etcher, the gas used was oxygen and the power was maintained at 300 W. The film was completely stripped on etching for 60 minutes. An optical dark field image of the SiC semiconductor substrate as seen in FIG. 5 shows a substantially smooth surface.

Although only certain features of the invention have been illustrated and described herein, many modifications and changes will occur to those skilled in the art. It is, therefore, to be understood that the appended claims are intended to cover all such modifications and changes as fall within the true spirit of the invention.

What is claimed:

1. A method of processing a semiconductor substrate, the method comprising:
depositing an amorphous hydrogenated carbon film on the semiconductor substrate using a low temperature plasma deposition process; and
performing at least one high temperature processing step on the semiconductor substrate.

2. The method of claim 1, wherein the semiconductor substrate comprises a compound semiconductor.

3. The method of claim 2, wherein the compound semiconductor is selected from the group consisting of SiC, SiGe, GaAs, GaN, and GaP.

4. The method of claim 3, wherein the compound semiconductor comprises SiC.

5. The method of claim 3, wherein the compound semiconductor is a semiconductor thin film.

6. The method of claim 1, wherein the low temperature plasma deposition process comprises a plasma enhanced chemical vapor deposition (PECVD) process.

7. The method of claim 1, wherein the amorphous hydrogenated carbon film comprises alternate layers of a hard and a soft layer, wherein one of the at least one hard layers is deposited on the semiconductor substrate.

8. The method of claim 1, wherein the amorphous hydrogenated carbon film comprises at least one hard layer deposited as a top most layer.

9. The method of claim 7, wherein the at least one hard layer has a thickness in a range of about 100 Angstroms to about 500 Angstroms, and wherein the at least one soft layer has a thickness in a range of about 300 Angstroms to about 1000 Angstroms.

10. The method of claim 1, wherein the amorphous hydrogenated carbon film comprises a blanket film.

11. The method of claim 1, wherein the amorphous hydrogenated carbon film comprises a patterned film.

12. The method of claim 1, wherein the high temperature processing step is performed at a temperature of at least about 1400 degrees C.

13. The method of claim 12, wherein the high temperature processing step comprises annealing the semiconductor substrate.

14. The method of claim 1, further comprising:
ion implanting at least one dopant species into the semiconductor substrate, wherein said ion implanting is performed prior to said depositing the amorphous hydrogenated carbon film; and
removing the amorphous hydrogenated carbon film after performing said at least one high temperature processing step.

15. The method of claim 14, wherein said removing the amorphous hydrogenated carbon film is performed using an oxygen plasma.

16. A method of processing a substrate comprising SiC, the method comprising:
depositing an amorphous hydrogenated carbon film on the substrate using a plasma enhanced chemical vapor deposition (PECVD) process; and
performing an annealing step on the substrate.

17. The method of claim 16, wherein the amorphous hydrogenated carbon film comprises alternate layers of a hard and a soft layer, wherein one of the at least one hard layers is deposited on the semiconductor substrate.

18. The method of claim 17, wherein the at least one hard layer has a thickness in a range of about 100 Angtroms to about 500 Angstroms, and wherein the at least one soft layer has a thickness in a range of about 300 Angstroms to about 1000 Angstroms.

19. The method of claim 17 further comprising:
ion implanting a p-type dopant species into at least one selected region of the substrate, wherein said ion implanting is performed prior to said depositing the amorphous hydrogenated carbon film; and
removing the amorphous hydrogenated carbon film after performing said annealing step.

20. A semiconductor device comprising a SiC substrate, wherein said SiC substrate is processed as follows:
ion implanting at least one dopant species into at least one selected region of said SiC substrate;
depositing an amorphous hydrogenated carbon film on said SiC substrate using a plasma enhanced chemical vapor deposition (PECVD) process;
performing a high temperature processing step on said SiC substrate; and
removing the amorphous hydrogenated carbon film after performing the high temperature processing step.

21. The semiconductor device of claim 20, wherein the high temperature processing step comprises annealing the SiC substrate, and wherein removing the film is performed using an oxygen plasma.

22. The semiconductor device of claim 21, wherein the semiconductor device forms a portion of an apparatus selected from the group consisting of a power converter, an inverter, electronics sensors, detectors, and associated control electronics, and signal conditioning electronics.

23. The semiconductor device of claim 20, wherein the semiconductor device is a device selected from the group consisting of a p-n diode, a p-i-n diode, a schottky diode, a metal oxide field effect transistor, an insulated gate bipolar transistor, a thyristor, and a gate turn-off thyristor.
